(19) United States
(12) Patent Application Publication
(10) Pub. No.: US 2010/0067717 A1
(43) Pub. Date: Mar. 18, 2010

(54) IMAGE PROCESSING APPARATUS AND CONTROL METHOD THEREOF

(75) Inventor: Kyu-eun PARK, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: Samsung Electronics Co., Ltd., Suwon-si (KR)

(21) Appl. No.: 12/479,166

(22) Filed: Jun. 5, 2009

(30) Foreign Application Priority Data
Sep. 12, 2008 (KR) 10-2008-0090536

(51) Int. Cl. H03G 9/00

(52) U.S. Cl. 381/102

(57) ABSTRACT

Disclosed are a circuit device which prevents an over-output of an audio signal in a certain band, a processing method of an audio signal, an image processing apparatus including the same and a control method thereof The image processing apparatus including: an image processor which processes an image signal; and an audio processor which filters an input audio signal to be in a first frequency band and limits a level of the audio signal in the first frequency band to a first output threshold value or less if the level of the audio signal in the first frequency band exceeds a predetermined first threshold value.

### CROSS-REFERENCE TO RELATED APPLICATION

This application claims priority from Korean Patent Application No. 10-2008-0090536, filed on Sep. 12, 2008, in the Korean Intellectual Property Office, the disclosure of which is incorporated herein by reference.

### BACKGROUND OF THE INVENTION

1. Field of the Invention

Apparatuses and methods consistent with the present invention relate to an image processing apparatus and a control method thereof, and more particularly, to a circuit device which prevents an over-output of an audio signal in a certain band, a processing method of an audio signal, an image processing apparatus including the same and a control method thereof.

2. Description of the Related Art

As electronic devices such as a digital TV, a mini-component system, an MP3 player and a mobile device are becoming slimmer, a speaker which is mounted in the devices is also getting smaller. As a result, a reproducible audio band becomes narrower and thus volume decreases.

A component which is outside of a reproducing limit of the speaker is not recognized by a user. However, in some cases, such a component may be recognized as bad noise. To resolve such a problem, sound in a certain band is filtered and limited in a circuit so as not to be transmitted to the speaker. However, an audio band which is reproduced in the speaker is not always consistent and differs depending on an output level.

For example, a low pitch component may be reproduced fully by the speaker if an output level is low. However, if the output level is high, the low pitch component is out of the reproducing limit of the speaker and is recognized as noise or sound crack. Particularly, it is typical that the audio signal is clipped if the output level is raised. A sound field technology which amplifies a low pitch has been developed, and such a clipping phenomenon of the audio signal is recognized more significantly as the low pitch is not easily recognized.

Accordingly, it would be preferable that an over-output of a speaker is prevented from a certain band if a frequency band of a speaker differs depending on an output level of an audio signal.

### SUMMARY OF THE INVENTION

According to an aspect of the present invention, there is provided an image processing apparatus including: an image processor which processes an image signal; and an audio processor which filters an input audio signal to be in a first frequency band and limits a level of the audio signal in the first frequency band to a first output threshold value or less if the level of the audio signal in the first frequency band exceeds a predetermined first threshold value.

The audio processor may adjust a gain of the audio signal in the first frequency band to be lower than a first setting value and limits the level of the audio signal in the first frequency band to the first output threshold value or less.

The audio processor may filter the input audio signal to be in a second frequency band which is different from the first frequency band, and limit a level of the audio signal in the second frequency band to a second output threshold value or less if the level of the audio signal in the second frequency band exceeds the second threshold value which is different from the first threshold value.

The audio processor may adjust a gain of the audio signal in the second frequency band to be lower than a second setting value and limits a level of the audio signal in the second frequency band to the second output threshold value or less.

The first threshold value may be smaller than the second threshold value.

The first frequency band may include a low pitch range, and the second frequency band may include a high frequency range.

According to another aspect of the present invention, there is provided an image processing apparatus including: an image processor which processes an image; and an audio processor which amplifies a level of a certain frequency band of an input audio signal, and limits the level of the input audio signal to an output threshold value or less if the level of the amplified audio signal in the certain band exceeds a predetermined threshold value.

The audio processor may adjust a gain of the input audio signal to be lower than a setting value and limits the level of the input audio signal to the output threshold value or less.

The certain frequency band may include a low frequency range.

According to another aspect of the present invention, there is provided a control method of an image processing apparatus, the control method including: filtering an input audio signal to be in a first frequency band; and limiting a level of the audio signal in the first frequency band to a first output threshold value or less if the level of the audio signal in the first frequency band exceeds a predetermined first threshold value.

The limiting the level of the audio signal in the first frequency band to the first output threshold value or less may include adjusting a gain of the audio signal in the first frequency band to be lower than a first setting value.

The control method may further include: filtering the input audio signal to be in a second frequency band which is different from the first frequency band; and limiting a level of the audio signal in the second frequency band to a second output threshold value or less if the level of the audio signal in the second frequency band exceeds a second threshold value which is different from the first threshold value.

The limiting the level of the audio signal in the second frequency band to the second output threshold value or less may include adjusting a gain of the audio signal in the second frequency band to be lower than a second setting value.

The first threshold value may be smaller than the second threshold value.

The first frequency band may include a low frequency range and the second frequency band includes a high frequency range.

According to another aspect of the present invention, there is provided a control method of an image processing apparatus, the control method including: amplifying a level of a certain frequency band of an input audio signal; and limiting a level of the input audio signal to an output threshold value or less if the level of the amplified audio signal in the certain band exceeds a predetermined threshold value.

The limiting the level of the input audio signal to the output threshold value or less may include adjusting a gain of the input audio signal to be lower than a setting value.

The certain frequency band may include a low frequency range.

According to another aspect of the present invention, there is provided a circuit device which prevents an over-output of a speaker, the circuit device including: a first filter which filters an audio signal to be in a first frequency band; a first comparator which determines whether a level of the audio signal in the first frequency band that passes through the first filter exceeds a predetermined first threshold value; and a first level limiter which limits the level of the audio signal in the first frequency band to a first output threshold value or less if the level of the audio signal in the first frequency band exceeds the first threshold value according to an output of the first comparator.

The first level limiter may adjust a gain of the audio signal in the first frequency band to be lower than a first setting value and limit the level of the audio signal in the first frequency band to the first output threshold value or less.

The circuit device may further include: a second filter which filters an audio signal to be in a second frequency band that is different from the first frequency band; a second comparator which determines whether a level of the audio signal in the second frequency band that passes through the second filter exceeds a second threshold value that is different from the first threshold value; and a second level limiter which limits a level of the audio signal in the second frequency band to a second output threshold value or less if the level of the audio signal in the second frequency band exceeds the second threshold value according to an output of the second comparator.

The second level limiter may adjust a gain of the audio signal in the second frequency band to be lower than a second setting value and limits the level of the audio signal in the second frequency band to the second output threshold value or less.

The first threshold value may be smaller than the second threshold value.

The first frequency band may include a low frequency range and the second frequency band includes a high frequency range.

According to another aspect of the present invention, there is provided a circuit device which prevents an over-output of a speaker, the circuit device including: a filter which amplifies a level of a certain frequency range of an input audio signal; a comparator which determines whether the level of the audio signal which passes through the filter exceeds a predetermined threshold value; and a level limiter which limits the level of the input audio signal to an output threshold value or less if the level of the audio signal that passes through the filter exceeds the threshold value according to an output of the comparator.

The level limiter may adjusts a gain of the input audio signal to be lower than a setting value and limit a level of the input audio signal to the output threshold value or less.

The certain frequency band may include a low frequency range.

According to another aspect of the present invention, there is provided a method of processing an audio signal to prevent an over-output of a speaker, the method including: filtering an input audio signal to be in a first frequency band; determining whether a level of the audio signal filtered to be in the first frequency band exceeds a predetermined first threshold value; and limiting a level of the audio signal in the first frequency band to a first output threshold value or less if the level of the audio signal in the first frequency band exceeds the first threshold value.

The limiting the level of the audio signal in the first frequency band to the first output threshold value or less may include adjusting a gain of the audio signal in the first frequency band to be lower than a first setting value.

The method may further include: filtering an audio signal to be in a second frequency band which is different from the first frequency band; determining whether the level of the audio signal filtered to be in the second frequency band exceeds a second threshold value which is different from the first threshold value; and limiting the level of the audio signal in the second frequency band to a second output threshold value or less if the level of the audio signal in the second frequency band exceeds the second threshold value.

The limiting the level of the audio signal in the second frequency band to the second output threshold value or less may include adjusting a gain of the audio signal in the second frequency band to be lower than a second setting value.

The first threshold value may be smaller than the second threshold value.

The first frequency band may include a low frequency range and the second frequency band may include a high frequency range.

According to another aspect of the present invention, there is provided a method of processing an audio signal to prevent an over-output of a speaker, the method including: amplifying a level of a certain frequency band of an input audio signal; determining whether a level of the audio signal which is amplified in the certain frequency band exceeds a predetermined threshold value; and limiting the level of the input audio signal to an output threshold value or less if the level of the amplified audio signal exceeds the threshold value.

The limiting the level of the input audio signal to the output threshold value or less may include adjusting a gain of the input audio signal to be lower than a setting value.

The certain frequency band may include a low frequency range.

### BRIEF DESCRIPTION OF THE DRAWINGS

The above and/or other aspects of the present invention will become apparent and more readily appreciated from the following description of the exemplary embodiments, taken in conjunction with the accompanying drawings of which:

FIG. 1 is a block diagram which illustrates a configuration of a circuit device to prevent an over-output of a speaker according to an exemplary embodiment of the present invention;

FIG. 2 is a graph which shows changes in waveforms of an audio signal according to the exemplary embodiment of the present invention;

FIG. 3 is a flowchart to describe a processing of an audio signal from the circuit device to prevent the over-output of the speaker according to the exemplary embodiment of the present invention;

FIG. 4 is a block diagram which illustrates a configuration of a circuit device to prevent an over-output of a speaker according to another exemplary embodiment of the present invention;

FIG. 5 is a graph which shows changes in waveforms of an audio signal according to the another exemplary embodiment of the present invention;

FIG. 6 is a flowchart to describe a processing of an audio signal from the circuit device to prevent the over-output of the speaker according to the another exemplary embodiment of the present invention; and

FIG. 7 is a control block diagram of an image processing apparatus according to the exemplary embodiment of the present invention.

### DETAILED DESCRIPTION OF EXEMPLARY EMBODIMENTS OF THE PRESENT INVENTION

Hereinafter, exemplary embodiments of the present invention will be described with reference to accompanying drawings, wherein like numerals refer to like elements and repetitive descriptions will be avoided as necessary.

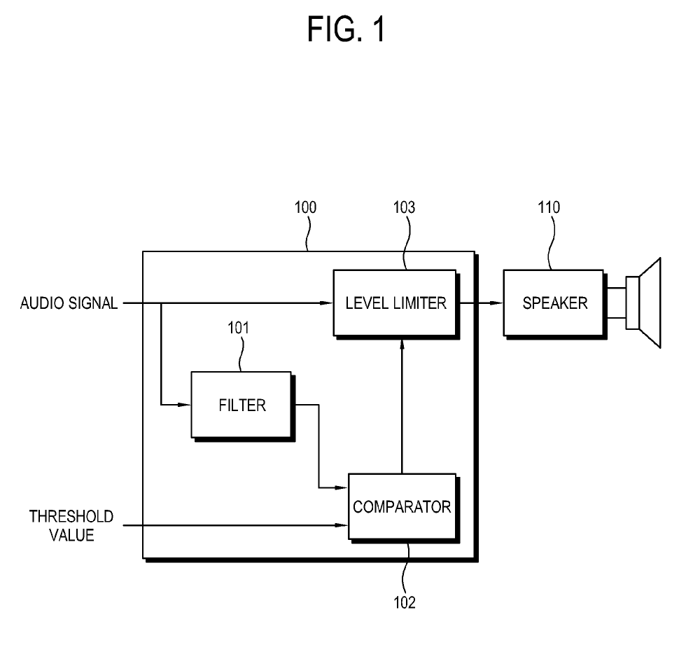

FIG. 1 is a block diagram which illustrates a configuration of a circuit device to prevent an over-output of a speaker according to an exemplary embodiment of the present invention.

As shown therein, a circuit device 100 which prevents an over-output of a speaker 110 according to the exemplary embodiment of the present invention includes a filter 101 which amplifies a level of a certain frequency band of an audio signal, a comparator 102 which compares a level of an audio signal with a predetermined threshold value and a level limiter 103 which limits a level of an audio signal to an output threshold value or less. According to the exemplary embodiment, the output threshold value may include an output value of an audio signal which is set to limit an over-output of the speaker 110 at a certain level or higher.

The filter 101 receives an audio signal and amplifies a level of a certain frequency band of the input audio signal to output the audio signal to the comparator 102. Here, the certain frequency band is not a certain single frequency, but a range which includes a certain band such as a high pitch range, a moderate pitch range, or a low pitch range. For example, the filter 101 amplifies a level of a low pitch range of an input audio signal and outputs the audio signal to the comparator 102. For purposes of convenience only, the level of the frequency band in the low pitch range is amplified according to the present exemplary embodiment, but not limited thereto. It is assumed that the low pitch range refers to a range of an audio signal in a certain frequency or lower while a high pitch range refers to a range of an audio signal in a certain frequency or higher.

The comparator 102 receives from the filter 101 an audio signal whose level is amplified in a low pitch range, and compares the level of the audio signal with a predetermined threshold value and outputs a comparison result to the level limiter 103.

If the level of the audio signal which is amplified in the low pitch range exceeds the threshold value according to the output of the comparator 102, the level limiter 103 limits the level of the audio signal to the output threshold value or less and outputs the audio signal to the speaker 110. According to the exemplary embodiment, the level limiter 103 may adjust a gain of the audio signal to be lower than a setting value to limit the level of the audio signal to the output threshold value or less.

That is, if the audio signal whose low pitch range is amplified exceeds the threshold value according to the comparison result of the comparator 102, the level limiter 103 reduces the gain of the audio signal to less than the setting value. If the audio signal whose low pitch range is amplified does not exceed the threshold value according to the comparison result, the level limiter 103 does not change the gain of the audio signal from the setting value. According to the exemplary embodiment, the setting value may correspond to a volume adjustment value set by a user.

In the circuit device 100 which prevents the over-output of the speaker 110 according to the exemplary embodiment of the present invention, an input audio signal is not input directly to the comparator 102. Rather, the audio signal whose level is amplified in the low pitch range is input to the comparator 102 through the filter 101 and is compared with the predetermined threshold value. If it is determined that the audio signal which has a relatively larger low pitch component exceeds the threshold value, the level limiter 103 reduces the gain of the audio signal. Accordingly, the level of the audio signal which has the relatively larger low pitch component has a reduced output.

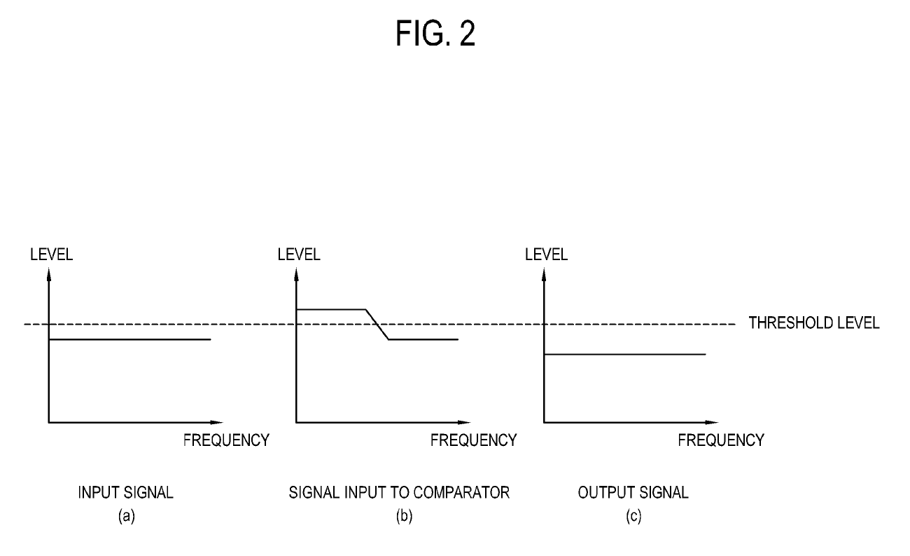

For example, FIG. 2 is a graph which illustrates changes in waveforms of the audio signal according to the exemplary embodiment of the present invention. If it is assumed that an audio signal which has a consistent level by frequency band is inputted as in (a) in FIG. 2, the audio signal whose level is amplified in the low pitch range is output as in (b) in FIG. 2 and is input to the comparator 102. Even though the input audio signal does not exceed a predetermined threshold value (dotted line), the audio signal which is input to the comparator 102 and whose level is amplified in the low pitch range exceeds the threshold value. Accordingly, the level limiter 103 limits a level of the audio signal as in (c) in FIG. 2 and outputs the audio signal.

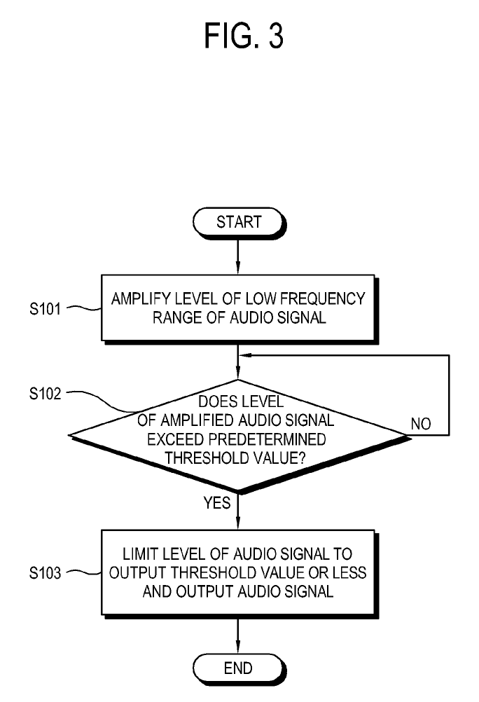

With the foregoing configuration, a method of processing the audio signal from the circuit device 100 which prevents the over-output of the speaker 110 according to the exemplary embodiment of the present invention will be described with reference to FIG. 3.

As shown in FIG. 3, a certain frequency band, e.g., a level of a low pitch range of the audio signal which is input through the filter 101 is amplified and input to the comparator 102 (S101). The comparator 102 determines whether the level of the audio signal which is amplified in the low pitch range exceeds the predetermined threshold value (S102). If the level of the audio signal which is amplified in the low pitch range exceeds the threshold value, the level limiter 103 limits the level of the audio signal input according to an output of the comparator 102 to the output threshold value or less and outputs the audio signal to the speaker 110 (S103).

If the audio signal includes the high pitch range together with the low pitch range in general, the employment of the foregoing method may result in a lowering of an overall output level. Accordingly, the circuit device 100 which prevents the over-output of the speaker 110 according to the present invention may have a following configuration.

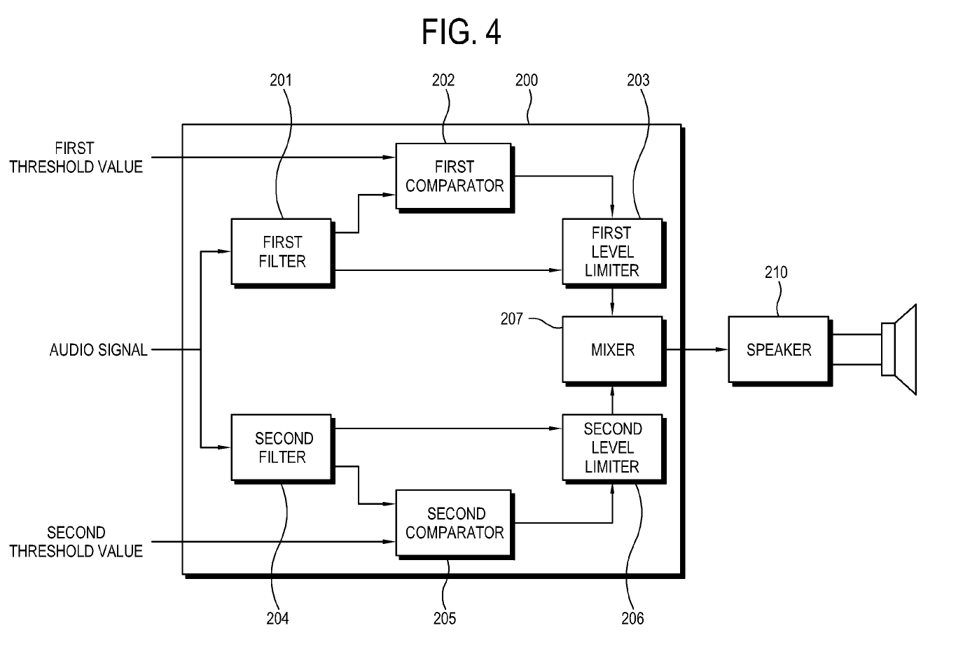

FIG. 4 is a block diagram which illustrates a configuration of a circuit device 200 which prevents an over-output of a speaker 210 according to another exemplary embodiment of the present invention.

As shown therein, the circuit device 200 which prevents the over-output of the speaker 210 according to the another exemplary embodiment of the present invention includes a first filter 201 which filters an audio signal to be in a first frequency band, a first comparator 202 which compares a level of an audio signal in a first frequency band with a predetermined first threshold value, a first level limiter 203 which limits the level of the audio signal in the first frequency band to a first output threshold value or less, a second filter 204 which filters an audio signal to be in a second frequency band, a second comparator 205 which compares a level of an audio signal in a second frequency band with a predetermined second threshold value, a second level limiter 206 which limits a level of an audio signal in a second frequency band to a second output threshold value or less and a mixer 207 which mixes the audio signal in the first and second frequency bands into a single audio signal. Here, the first frequency band may include a low frequency band while the second frequency band may include a high frequency band based on a certain frequency.

According to the exemplary embodiment, the first output threshold value or the second output threshold value may include an output value of an audio signal which is set to limit an over-output of the speaker at a certain level or higher.

According to the exemplary embodiment, the first level limiter 203 may adjust a gain of the audio signal to be lower than a first setting value to thereby limit the level of the audio signal to the first output threshold value or less. Also, the second level limiter 206 may adjust the gain of the audio signal to be lower than a second setting value to thereby limit the level of the audio signal to the second output threshold value or less.

The first filter 201 and the second filter 204 receive an audio signal, filter the input audio signal into a first portion in the first frequency band and a second portion in the second frequency band and output the audio signal to the first comparator 202 and the second comparator 205, respectively. For example, the first filter 201 includes a high-pass filter, removes a high pitch range of an input audio signal and outputs a first portion of the audio signal in the low pitch range to the first comparator 202 while the second filter 204 includes a low-pass filter, removes a low pitch range of an input audio signal and outputs a second portion of the audio signal in the high pitch range to the second comparator 205. For purposes of convenience only, the audio signal is separated into the low pitch range and the high pitch range according to the present exemplary embodiment, but not limited thereto.

The first comparator 202 receives a first portion of the audio signal in the low pitch range from the first filter 201, compares the first portion of the audio signal with the first threshold value and outputs the comparison result to the first level limiter 203. Also, the second comparator 205 receives a second portion of the audio signal in a high pitch range from the second filter 204, compares the second portion of the audio signal with the second threshold value and outputs the comparison result to the second level limiter 206. Here, the first threshold value and the second threshold value are different values preferably. More preferably, the first threshold value is smaller than the second threshold value.

If the level of the first portion of the audio signal in the low pitch range exceeds the first threshold value according to the comparison result of the first comparator 202, the first level limiter 203 adjusts a gain of the first portion of the audio signal in the low pitch range to be lower than the first setting value. The first level limiter 203 outputs to the mixer 207 the first portion of the audio signal in the low pitch range whose gain is adjusted. Accordingly, the first portion of the audio signal in the low pitch range has a limited level.

If the level of the second portion of the audio signal in the high pitch range exceeds the second threshold value according to the comparison result of the second comparator 205, the second level limiter 206 adjusts a gain of the second portion of the audio signal in the high pitch range to be lower than the second setting value. The second level limiter 206 outputs to the mixer 207 the second portion of the audio signal in the high pitch range whose gain is adjusted. Accordingly, the second portion of the audio signal in the high pitch range has a limited level.

For example, the second threshold value may be set to be higher than the first threshold value. A change in the gain which is adjusted to be lower than the second setting value may be set to be smaller than that of the gain adjusted to be lower than the first setting value. Thus, an output of the first portion of the audio signal in the low pitch range may be limited to be relatively lower than an output of the second portion of the audio signal in the high pitch range. The first and second setting values may be equal, the first and second threshold values may be equal or each setting value may correspond to a volume adjustment value set by a user.

The mixer 207 receives first and second portions of an audio signal in a low pitch range and a high pitch range from the first level limiter 203 and the second level limiter 206, respectively, and mixes the portions of the audio signal in the low and high pitch ranges into a single audio signal to output the signal to the speaker 210.

In the circuit device 200 which prevents the over-output of the speaker 210 according to the another exemplary embodiment of the present invention, the input audio signal is separated into the low pitch range and the high pitch range by the first filter 201 and the second filter 204 and input to the first comparator 202 and the second comparator 205, respectively. Then, the first and second portions of the audio signal are compared with the first and second threshold values which are different from each other, to limit the output level of the audio signal. Particularly, if the first threshold value with respect to the low pitch range is set to be lower than the second threshold value with respect to the high band, only the low pitch range may be separated from the input audio signal and limited at a further lower level.

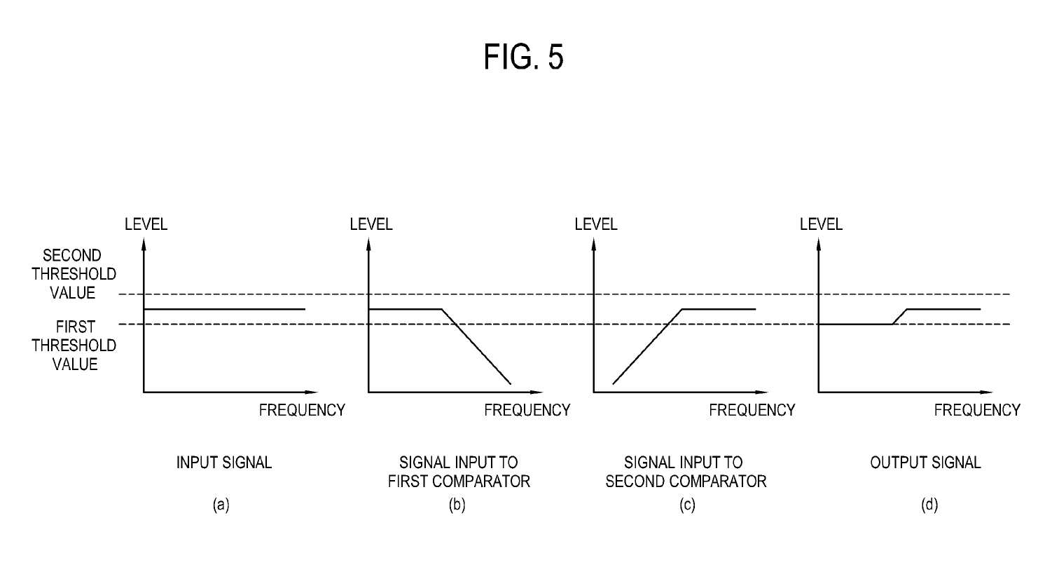

For example, FIG. 5 is a graph which illustrates changes in waveforms of an audio signal according to the another exemplary embodiment of the present invention. If it is assumed that an audio signal at a consistent level is input by frequency band as in (a) in FIG. 5, an audio signal which has only a separated low pitch range is output by the first filter 201 as in (b) in FIG. 5 and input to the first comparator 202 while an audio signal which has only a separated high pitch range is output by the second filter 204 as in (c) in FIG. 5 and input to the second comparator 205. If the first threshold value (dotted line) is set to be lower than the second threshold value (dotted line), the portion of the audio signal in the high pitch range which is input to the second comparator 205 does not exceed the second threshold value. However, the portion of the audio signal in the low pitch range which is input to the first comparator 202 exceeds the first threshold value. Accordingly, the first level limiter 203 limits the level of the portion of the audio signal in the low pitch range to the first threshold value or less and outputs the audio signal, and the mixer 207 outputs the audio signal as in (d) in FIG. 5.

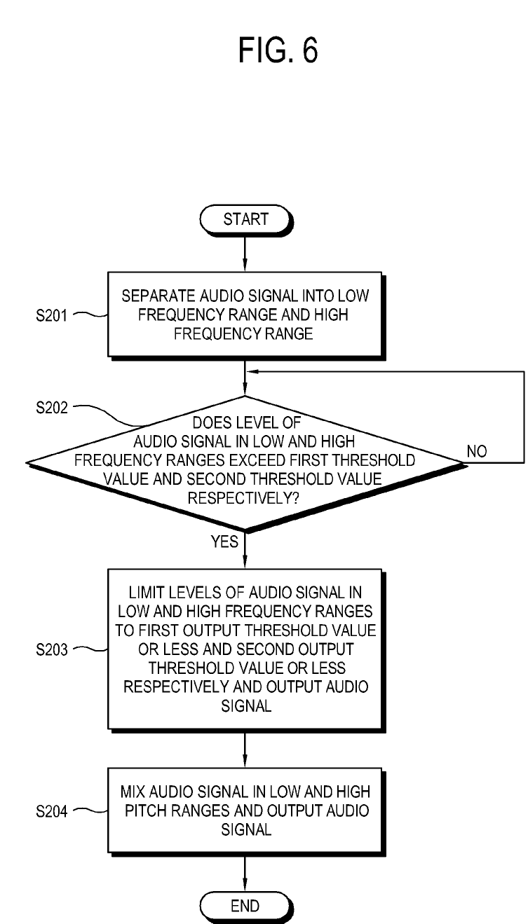

With the foregoing configuration, a method of processing the audio signal from the circuit device 200 which prevents the over-output of the speaker 210 according to the another exemplary embodiment of the present invention will be described with reference to FIG. 6.

As shown in FIG. 6, the audio signal which is input through the first filter 201 and the second filter 204 is separated into the first frequency band and the second frequency band, e.g., a low pitch range and a high pitch range, and is output to the first comparator 202 and the second comparator 205, respectively (S201). The first comparator 202 determines whether the level of the low pitch range exceeds the predetermined first threshold value, and the second comparator 205 determines whether the level of the high pitch range exceeds the predetermined second threshold value (S202). Here, the first threshold value and the second threshold value are preferably different from each other. More preferably, the first threshold value is smaller than the second threshold value. If the level of the portion of the audio signal in the low pitch range exceeds the first threshold value according to the output of the first comparator 202, the first level limiter 203 limits the level of the portion of the audio signal in the low pitch range to the first output threshold value or less and outputs the audio signal to the mixer 207. If the level of the portion of the audio signal in the high pitch range exceeds the second threshold value according to the output of the second comparator 205, the second level limiter 206 limits the level of the portion of the audio signal in the high pitch range to the second output threshold value or less and outputs the audio signal to the mixer 207 (S203). The mixer 207 receives the portions of the audio signal in the low pitch range and the high pitch range from the first level limiter 203 and the second level limiter 206, respectively, and mixes the portions of the audio signal in the low and high pitch ranges into a single audio signal and outputs the audio signal to the speaker 210 (S204).

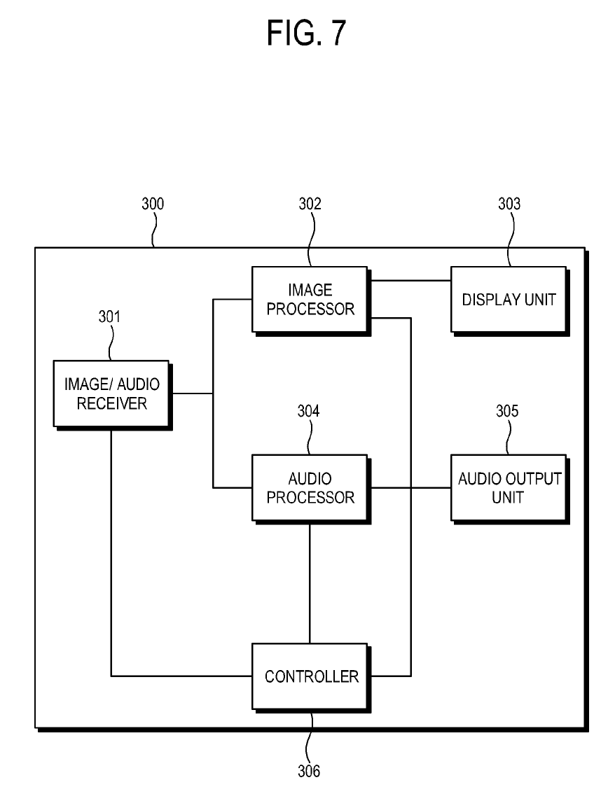

FIG. 7 is a control block diagram which illustrates an image processing apparatus 300 according to the exemplary embodiment of the present invention.

As shown therein, the image processing apparatus 300 according to the exemplary embodiment of the present invention processes an image and an audio which is received through a satellite, a wired cable, a wired/wireless communication network or an external device, and displays the image and the audio.

As shown in FIG. 7, the image processing apparatus 300 according to the exemplary embodiment of the present invention includes an image/audio receiver 301 which receives an image and an audio, an image processor 302 which processes the received image, a display unit 303 which displays the image processed by the image processor 302, an audio processor 304 which processes the received audio, an audio output unit 305 which outputs the audio processed by the audio processor 304 and a controller 306 which controls operations of the foregoing elements as a whole.

The image/audio receiver 301 receives an image and an audio from a satellite, a wired cable, a wired/wireless communication network or an external device, and transmits the image and the audio to the image processor 302 and the audio processor 304, respectively. The image/audio receiver 301 may include various configurations to receive an image and an audio. For example, the image/audio receiver 301 may include an antenna (not shown) which receives an airwave broadcasting signal in a wireless manner, or receive a broadcasting signal in a wired manner by being connected to a cable from a broadcasting station. Further, the image/audio receiver 301 may include various connectors which receive an image signal and an audio signal from an external device such as a computer, a digital versatile disc (DVD) player, a game device, etc.

The image processor 302 processes an image received by the image/audio receiver 301 to be displayed on the display unit 303. Accordingly, the image processor 302 may employ various functions including a decoding function, a picture in picture (PIP) function, a scaling function, a screen adjustment function, etc. with respect to a received image.

The audio processor 304 processes an audio received by the image/audio receiver 301, and outputs the processed audio to the audio output unit 305. The audio processor 304 may include a circuit device which prevents the over-output of the speaker according to the exemplary embodiment of the present invention. Repetitive description will be avoided.

The display unit 303 may include a liquid crystal display (LCD), a plasma display panel (PDP), a cathode ray tube (CRT), etc. and displays thereon the image processed by the image processor 302.

The audio output unit 305 outputs an audio processed by the audio processor 304. The audio output unit 305 may include a plurality of speakers (not shown) which are provided with a plurality of channels.

Although a few exemplary embodiments of the present invention have been shown and described, it will be appreciated by those skilled in the art that changes may be made in these exemplary embodiments without departing from the principles and spirit of the invention, the scope of which is defined in the appended claims and their equivalents.

1. An image processing apparatus comprising:
an image processor which processes an image signal; and
an audio processor which filters an input audio signal into a first portion in a first frequency band and limits a level of the first portion of the audio signal in the first frequency band to a first output threshold value or less if the level of the first portion of the audio signal in the first frequency band exceeds a first predetermined threshold value.

2. The image processing apparatus according to claim 1, wherein the audio processor adjusts a gain of the first portion of the audio signal in the first frequency band to be lower than a first setting value and limits the level of the first portion of the audio signal in the first frequency band to the first output threshold value or less.

3. The image processing apparatus according to claim 2, wherein the audio processor further filters the input audio signal into a second portion in a second frequency band which is different from the first frequency band, and limits a level of the second portion of the audio signal in the second frequency band to a second output threshold value or less if the level of the second portion of the audio signal in the second frequency band exceeds a second predetermined threshold value which is different from the first predetermined threshold value.

4. The image processing apparatus according to claim 3, wherein the audio processor adjusts a gain of the second portion of the audio signal in the second frequency band to be lower than a second setting value and limits a level of the second portion of the audio signal in the second frequency band to the second output threshold value or less.

5. The image processing apparatus according to claim 4, wherein the first predetermined threshold value is smaller than the second predetermined threshold value.

6. The image processing apparatus according to claim 5, wherein the first frequency band comprises a low frequency range, and the second frequency band comprises a high frequency range.

7. An image processing apparatus comprising:
an image processor which processes an image; and
an audio processor which amplifies a first level of an input audio signal in a certain frequency band, and limits a second level of the input audio signal to an output threshold value or less if the amplified first level of the audio signal in the certain frequency band exceeds a predetermined threshold value.

8. The image processing apparatus according to claim 7, wherein the audio processor adjusts a gain of the input audio signal to be lower than a setting value and limits the second level of the input audio signal to the output threshold value or less.

9. The image processing apparatus according to claim 8, wherein the certain frequency band comprises a low frequency range.

10. A control method of an image processing apparatus, the control method comprising:
filtering an input audio signal into a first portion in a first frequency band; and
limiting a level of the first portion of the audio signal in the first frequency band to a first output threshold value or less if the level of the first portion of the audio signal in the first frequency band exceeds a first predetermined threshold value.

11. The control method according to claim 10, wherein the limiting the level of the first portion of the audio signal in the first frequency band to the first output threshold value or less comprises adjusting a gain of the first portion of the audio signal in the first frequency band to be lower than a first setting value.

12. The control method according to claim 11, further comprising:
further filtering the input audio signal into a second portion in a second frequency band which is different from the first frequency band; and
limiting a level of the second portion of the audio signal in the second frequency band to a second output threshold value or less if the level of the second portion of the audio signal in the second frequency band exceeds a second predetermined threshold value which is different from the first predetermined threshold value.

13. The control method according to claim 12, wherein the limiting the level of the second portion of the audio signal in the second frequency band to the second output threshold value or less comprises adjusting a gain of the second portion of the audio signal in the second frequency band to be lower than a second setting value.

14. The control method according to claim 13, wherein the first predetermined threshold value is smaller than the second predetermined threshold value.

15. The control method according to claim 14, wherein the first frequency band comprises a low frequency range and the second frequency band comprises a high frequency range.

16. A control method of an image processing apparatus, the control method comprising:
amplifying a first level of an input audio signal in a certain frequency band; and
limiting a second level of the input audio signal to an output threshold value or less if the amplified first level of the audio signal in the certain frequency band exceeds a predetermined threshold value.

17. The control method according to claim 16, wherein the limiting the second level of the input audio signal to the output threshold value or less comprises adjusting a gain of the input audio signal to be lower than a setting value.

18. The control method according to claim 17, wherein the certain frequency band comprises a low frequency range.

19. A circuit device which prevents an over-output of a speaker, the circuit device comprising:
a first filter which filters an audio signal into a first portion in a first frequency band;
a first comparator which determines whether a level of the first portion of the audio signal in the first frequency band that passes through the first filter exceeds a first predetermined threshold value; and
a first level limiter which limits a level of the first portion of the audio signal in the first frequency band to a first output threshold value or less if the level of the first portion of the audio signal in the first frequency band exceeds the first predetermined threshold value according to an output of the first comparator.

20. The circuit device according to claim 19, wherein the first level limiter adjusts a gain of the first portion of the audio signal in the first frequency band to be lower than a first setting value and limits the level of the first portion of the audio signal in the first frequency band to the first output threshold value or less.

21. The circuit device according to claim 20, further comprising:
a second filter which further filters the audio signal into a second portion in a second frequency band that is different from the first frequency band;
a second comparator which determines whether a level of the second portion of the audio signal in the second frequency band that passes through the second filter exceeds a second predetermined threshold value that is different from the first predetermined threshold value; and
a second level limiter which limits a level of the second portion of the audio signal in the second frequency band to a second output threshold value or less if the level of the audio signal in the second frequency band exceeds the second predetermined threshold value according to an output of the second comparator.

22. The circuit device according to claim 21, wherein the second level limiter adjusts a gain of the second portion of the audio signal in the second frequency band to be lower than a second setting value and limits the level of the second portion of the audio signal in the second frequency band to the second output threshold value or less.

23. The circuit device according to claim 22, wherein the first predetermined threshold value is smaller than the second predetermined threshold value.

24. The circuit device according to claim 23, wherein the first frequency band comprises a low frequency range and the second frequency band comprises a high frequency range.

25. A circuit device which prevents an over-output of a speaker, the circuit device comprising:
a filter which amplifies a first level of an input audio signal in a certain frequency range;
a comparator which determines whether the amplified first level of the audio signal which passes through the filter exceeds a predetermined threshold value; and
a level limiter which limits a second level of the input audio signal to an output threshold value or less if the amplified first level of the audio signal that passes through the filter exceeds the threshold value according to an output of the comparator.

26. The circuit device according to claim 25, wherein the level limiter adjusts a gain of the input audio signal to be lower than a setting value and limits the second level of the input audio signal to the output threshold value or less.

27. The circuit device according to claim 26, wherein the certain frequency band comprises a low frequency range.

28. A method of processing an audio signal to prevent an over-output of a speaker, the method comprising:
filtering an input audio signal into a first portion in a first frequency band;
determining whether a level of the first portion of the audio signal in the first frequency band exceeds a first predetermined threshold value; and
limiting a level of the audio signal in the first frequency band to a first output threshold value or less if the level of the first portion of the audio signal in the first frequency band exceeds the first predetermined threshold value.

29. The method according to claim 28, wherein the limiting the level of the first portion of the audio signal in the first frequency band to the first output threshold value or less comprises adjusting a gain of the first portion of the audio signal in the first frequency band to be lower than a first setting value.

30. The method according to claim 29, further comprising:
further filtering the input audio signal into a second portion in a second frequency band which is different from the first frequency band;
determining whether a level of the second portion of the audio signal in the second frequency band exceeds a second predetermined threshold value which is different from the first predetermined threshold value; and
limiting the level of the second portion of the audio signal in the second frequency band to a second output threshold value or less if the level of the audio signal in the second frequency band exceeds the second predetermined threshold value.

31. The method according to claim 30, wherein the limiting the level of the second portion of the audio signal in the second frequency band to the second output threshold value or less comprises adjusting a gain of the second portion of the audio signal in the second frequency band to be lower than a second setting value.

32. The method according to claim 31, wherein the first predetermined threshold value is smaller than the second predetermined threshold value.

33. The method according to claim 32, wherein the first frequency band comprises a low frequency range and the second frequency band comprises a high frequency range.

34. A method of processing an audio signal to prevent an over-output of a speaker, the method comprising:
amplifying a first level of an input audio signal in a certain frequency band;
determining whether the amplified first level of the audio signal in the certain frequency band exceeds a predetermined threshold value; and
limiting a second level of the input audio signal to an output threshold value or less if the amplified first level of the audio signal exceeds the threshold value.

35. The method according to claim 34, wherein the limiting the second level of the input audio signal to the output threshold value or less comprises adjusting a gain of the input audio signal to be lower than a setting value.

36. The method according to claim 35, wherein the certain frequency band comprises a low frequency range.

37. The image processing apparatus according to claim 3, wherein, after limiting the level of the first and second portions of the audio signal, the audio processor mixes the first and second portions of the audio signal to form an output audio signal, and outputs the output audio signal to a speaker.

38. The image processing apparatus according to claim 7, wherein the audio processor outputs the audio signal at the second level which has been limited to the output threshold or less to a speaker.

39. (canceled)

40. (canceled)
